(19) United States
(12) Patent Application Publication
(10) Pub. No.: US 2013/0127485 A1
(43) Pub. Date: May 23, 2013

(54) PRINTED CIRCUIT BOARD TESTING DEVICE

(71) Applicants: TINA MAO, DAXI TOWNSHIP (TW); CHING-FENG HSIEH, TAIPEI CITY (TW)

(72) Inventors: TINA MAO, DAXI TOWNSHIP (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/325,159

(22) Filed: Dec. 14, 2011

(30) Foreign Application Priority Data
Nov. 18, 2011 (TW) 100142249

(51) Int. Cl. G01R 31/20

(52) U.S. Cl. 324/750.25

(57) ABSTRACT

A printed circuit board testing device for performing electrical tests on a printed circuit board having test contacts includes a test platform. An installable and uninstallable positioning module is disposed on the test platform and adapted to receive the printed circuit board. The positioning module has through-holes corresponding in position to the test contacts. A dial module is disposed between the test platform and the positioning module, and has a needle corresponding in position to the through-holes, such that the distance between the dial module and the positioning module can be altered to cause the needle to penetrate a corresponding one the through-holes, insert into the positioning module, and come into contact with the test contacts to facilitate the electrical test. The printed circuit board testing device can perform electrical tests on any printed circuit boards having the test contacts, by changing the positioning module and the dial module.

### CROSS-REFERENCE TO RELATED APPLICATION

This non-provisional application claims priority under 35 U.S.C. §119(a) on Patent Application No(s). 100142249 filed in Taiwan, R.O.C. on Nov. 18, 2011, the entire contents of which are hereby incorporated by reference.

### FIELD OF TECHNOLOGY

The present invention relates to printed circuit board testing devices, and more particularly, to a device for performing electrical tests on test contacts on a printed circuit board.

### BACKGROUND

According to related prior art, upon completion of a circuit layout of a printed circuit board, it is necessary to perform electrical tests on the printed circuit board to verify that the printed circuit board is capable of providing normal electrical connection. Furthermore, according to the related prior art, a conventional printed circuit board testing device for testing the printed circuit board is provided.

Regarding the conventional printed circuit board testing device, a test worker performs a contact-style connection test on the printed circuit board by means of a test line (or a bus cable) and an electronic component (such as a monitor, a power supply, or a keyboard), and the test worker determines whether the printed circuit board is functioning well by evaluating whether the electronic component is functioning well. Given a plurality of printed circuit boards with the same circuit layout, assuming that the electronic component is shared by and between the printed circuit boards, it is feasible to position the electronic component in the printed circuit board testing device in advance to enable a test to be performed intensively and quickly on the printed circuit boards having the same circuit layout.

However, the aforesaid printed circuit board testing device is only effective in performing dedicated tests on printed circuit boards having the same circuit layout as opposed to having different circuit layouts. As a result, new different printed circuit board testing devices have to be designed for performing tests on printed circuit boards having different circuit layouts. The process of designing new different printed circuit board testing devices takes much time and incurs costs.

In view of the aforesaid drawbacks of the prior art, the present invention provides a printed circuit board testing device for overcoming the aforesaid drawbacks of the prior art, by speeding up the process of developing the printed circuit board testing device and cutting the costs incurred therein.

### SUMMARY

It is an objective of the present invention to provide a printed circuit board testing device for keeping shared test circuits of printed circuit boards in different devices under test (DUTs) and changing unshared test circuits of the printed circuit boards to perform various electrical tests on the printed circuit boards quickly.

Another objective of the present invention is to provide a printed circuit board testing device for performing electrical tests on any types of the printed circuit boards by means of a replaceable dial module.

Yet another objective of the present invention is to provide a printed circuit board testing device capable of hiding the dial module to protect the dial module, for example, protecting a needle disposed above the dial module, when the printed circuit board testing device is not in use.

In order to achieve the above and other objectives, the present invention provides a printed circuit board testing device for performing electrical tests on a printed circuit board having test contacts. The printed circuit board testing device comprises a test platform, a positioning module, and a dial module. The test platform carries at least one electronic component, with a correlation between the at least one electronic component and the test contacts as far as the electrical tests are concerned. The positioning module is mountable on and dismountable from the test platform and comprises a base formed thereon with a receiving recess having through-holes and receiving the printed circuit board, wherein the test contacts of the printed circuit board face the through-holes. The dial module comprises a bottom plate and a needle and is selectively disposed between the test platform and the positioning module, wherein the needle is disposed on the bottom plate, corresponds in position to the through-holes, and is capable of penetrating the through-holes and inserting into the receiving recess to abut against the test contacts.

Hence, a printed circuit board testing device of the present invention is capable of performing electrical tests on a plurality of printed circuit boards each having at least one test contact thereon. The printed circuit board testing device keeps shared test circuits of the printed circuit boards and swaps a positioning module and a dial module of the printed circuit board testing device for each other, such that the printed circuit board testing device can test the printed circuit boards.

Unlike the prior art, the present invention provides a printed circuit board testing device that dispenses with the hassles of redesigning or remaking a dedicated printed circuit board testing device but performs electrical tests on a plurality of printed circuit boards by making minute changes thereto.

### BRIEF DESCRIPTION

Objectives, features, and advantages of the present invention are hereunder illustrated with specific embodiments in conjunction with the accompanying drawings, in which:

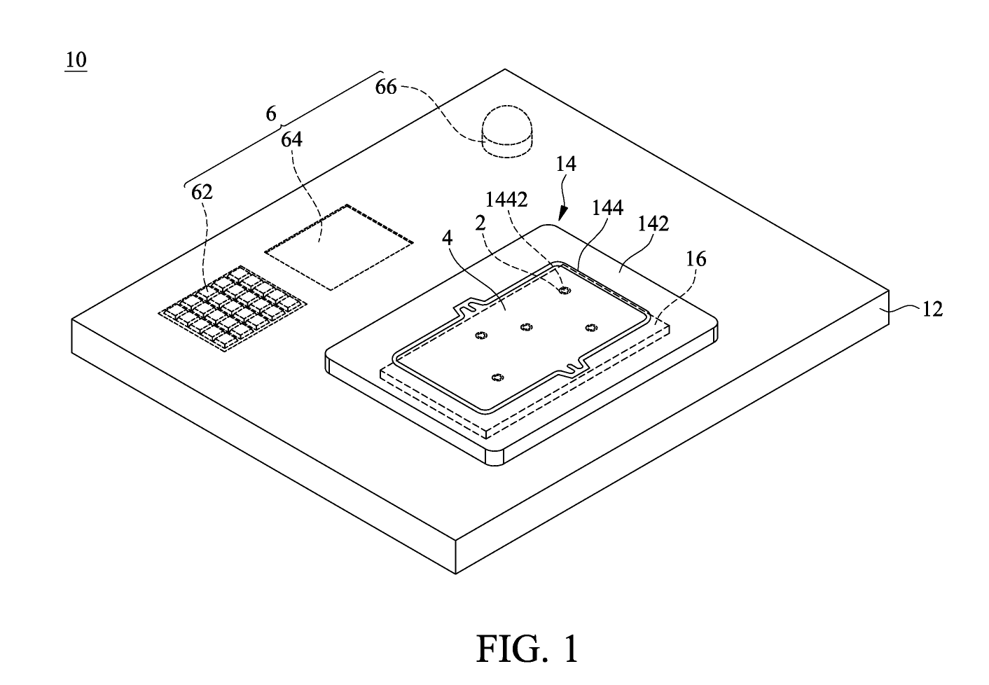

FIG. 1 is a schematic view of a printed circuit board testing device according to the first embodiment of the present invention;

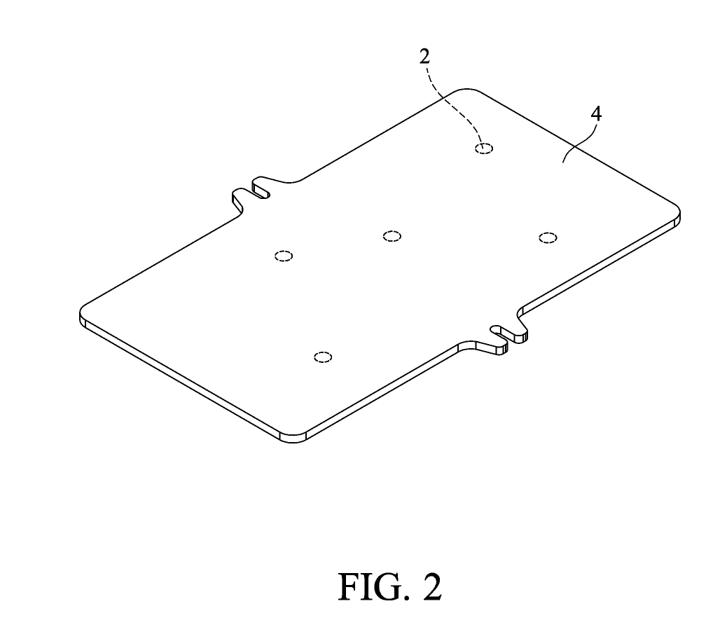

FIG. 2 is a schematic view of distribution of at least one test contact a the printed circuit board shown in FIG. 1;

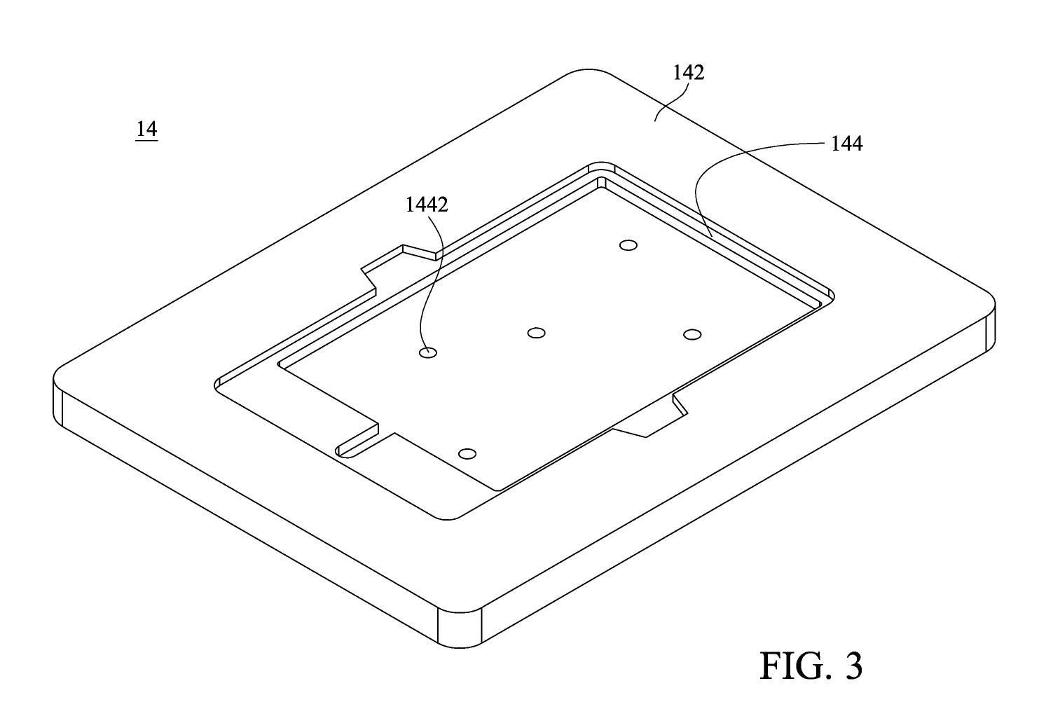

FIG. 3 is a structural schematic view of a positioning module shown in FIG. 1;

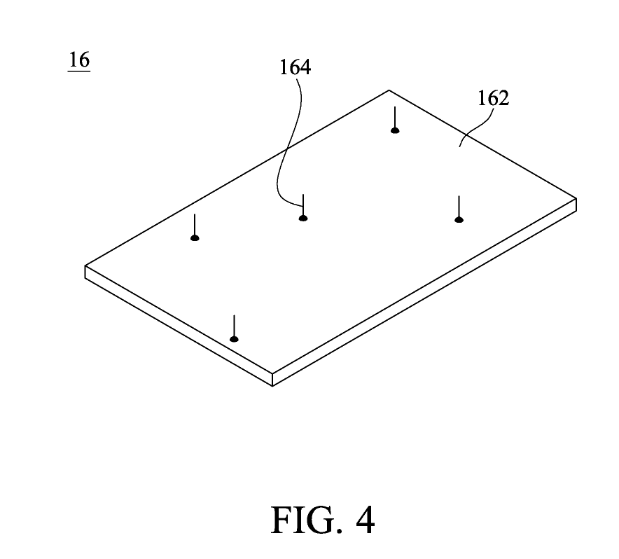

FIG. 4 is a structural schematic view of a dial module shown in FIG. 1;

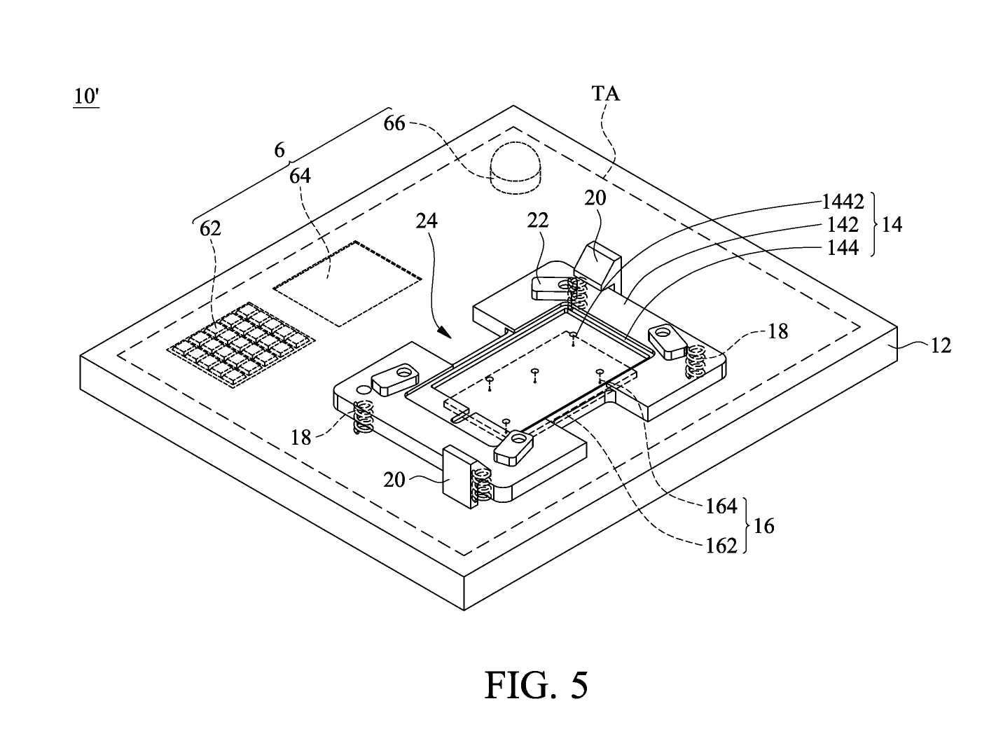

FIG. 5 is a structural schematic view of a printed circuit board testing device according to the second embodiment of the present invention;

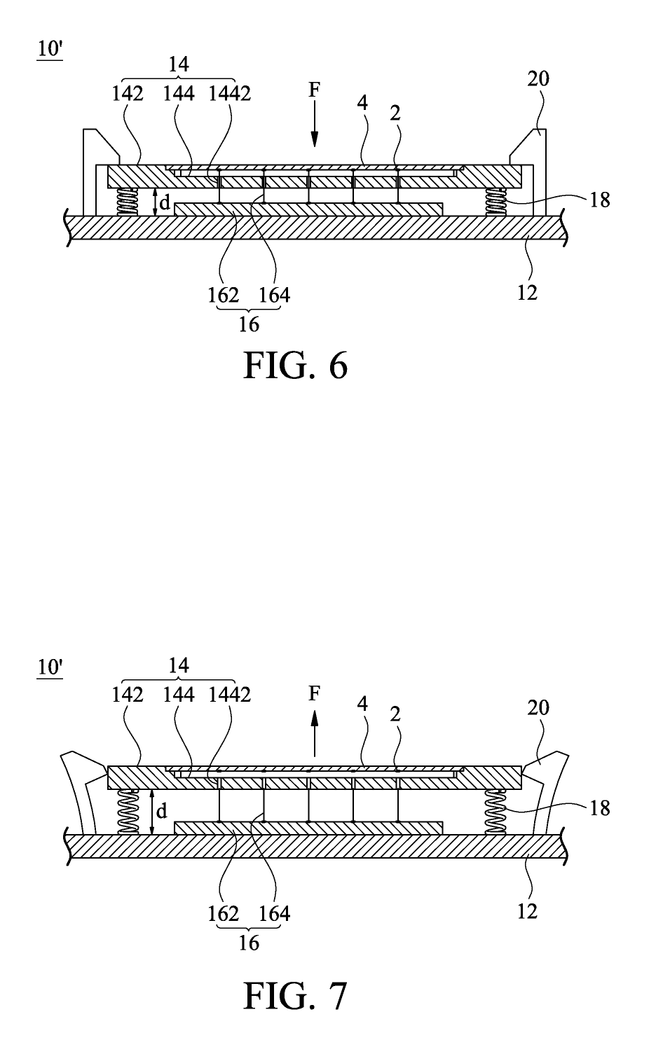

FIG. 6 is a cross-sectional schematic view of the printed circuit board testing device shown in FIG. 5 after application of an external force thereto; and

FIG. 7 is a cross-sectional schematic view of the printed circuit board testing device shown in FIG. 5 after removal of the external force therefrom.

### DETAILED DESCRIPTION

Referring to FIG. 1, there is shown a schematic view of a printed circuit board testing device 10 according to the first embodiment of the present invention. As shown in FIG. 1, the printed circuit board testing device 10 performs electrical tests on a printed circuit board 4 having at least one test contact 2. In this regard, the first embodiment of the present invention is exemplified by five said test contacts 2. Besides, in an embodiment, the printed circuit board 4 is applicable to portable communication devices. Furthermore, the detailed distribution of the test contacts 2 of the printed circuit board 4 is illustrated with FIG. 2. For example, the test contacts 2 are display signal output test contacts, touch-control signal input test contacts, power supply test contacts, keyboard signal input test contacts, or audio signal output test contacts.

The printed circuit board testing device 10 comprises a test platform 12, a positioning module 14, and a dial module 16.

The test platform 12 carries the positioning module 14 and the dial module 16. At least one electronic component 6 is disposed on the test platform 12 in advance, such that the printed circuit board 4 can perform related electrical tests on the electronic component 6. Examples of the electronic component 6 include a keyboard, a monitor, and a loudspeaker. The at least one electronic component 6 interacts directly or indirectly with the test contacts 2 on the printed circuit board 4 by means of a circuit layout, a testing line, or a bus. That is to say, there is a correlation between the at least one electronic component 6 of the test platform 12 and the test contacts 2 as far as the electrical tests are concerned. For example, on the printed circuit board 4, the test contacts 2 associated with an audio signal output are electrically connected to the loudspeaker such that, upon determination as to whether the loudspeaker has generated the audio signal, the electrical tests are performed on the printed circuit board 4.

The positioning module 14 can be mounted on and dismounted from the test platform 12. That is to say, the positioning module 14 is flexibly changeable according to the dimensions and size of the printed circuit board 4 and the requirements of the electrical tests. Furthermore, in addition to being mountable on the test platform 12, the positioning module 14 comprises a base 142. A receiving recess 144 with through-holes 1442 is formed on the base 142, as shown in FIG. 1 and FIG. 3. The receiving recess 144 receives the printed circuit board 4. In this regard, the receiving recess 144 corresponds in shape to the printed circuit board 4, such that the printed circuit board 4 can be positioned in and fixed to the receiving recess 144; hence, the test contacts 2 on the printed circuit board 4 can be accurately aligned with the dial module 16. Besides, the through-holes 1442 of the receiving recess 144 correspond in position to the test contacts 2 on the printed circuit board 4, respectively. In an embodiment, the test contacts 2 face the through-holes 1442; in other words, the test contact-disposed side of the printed circuit board 4 faces the receiving recess 144.

The dial module 16 is selectively disposed between the test platform 12 and the positioning module 14. The dial module 16 comprises a bottom plate 162 and at least one needle 164, as shown in FIG. 4. The at least one needle 164 is disposed on the bottom plate 162 and corresponds in position to the through-holes 1442 of the receiving recess 144, such that the at least one needle 164, the through-holes 1442, and the test contacts 2 are vertically aligned with each other. In an embodiment, the at least one needle 164 penetrates the through-holes 1442 and inserts into the receiving recess 144 to come into contact with and abut against the test contacts 2 for performing electrical tests. When the printed circuit board 4 is not ready for undergoing the electrical tests, the at least one needle 164 is received in the through-holes 1442, such that the at least one needle 164 is hidden in or beneath the through-holes 1442 and protected.

The positioning module 14 and the dial module 16 are changeable. Hence, users can change the positioning module 14 and the dial module 16 flexibly so as to meet variable electrical test requirements of the printed circuit board 4, thereby dispensing with the hassles of changing the test platform 12 and/or the at least one electronic component 6. Hence, the printed circuit board testing device 10 of the present invention can keep a shared electronic component and a circuit layout thereof on the test platform 12.

Referring to FIG. 5, there is shown a structural schematic view of a printed circuit board testing device 10′ according to the second embodiment of the present invention. As shown in FIG. 5, in addition to the test platform 12, the positioning module 14, and the dial module 16 which are described in the first embodiment, the printed circuit board testing device 10′ in the second embodiment further comprises an elevating unit 18, a fixing unit 20, a clamping unit 22, and an accessing unit 24.

The elevating unit 18 alters the distance between the positioning module 14 and the dial module 16. In this embodiment, the elevating unit 18 is disposed between the test platform 12 and the positioning module 14. The elevating unit 18 is positioned at a corner of the receiving recess 144. For example, the elevating unit 18 is a spring for generating a compressing force and a restoring force.

For example, with the printed circuit board 4 being positioned in and fixed to the receiving recess 144, an external force F exerted upon the positioning module 14 is accompanied by the compressing force generated from the elevating unit 18 and adapted to decrease the distance d between the positioning module 14 and the dial module 16 (see FIG. 6 and FIG. 7) and enable the at least one needle 164 to penetrate the through-holes 1442, insert into the receiving recess 144, and come into contact with and abut against the test contacts 2 of the printed circuit board 4, as shown in FIG. 6. By contrast, when the external force F vanishes, the elevating unit 18 generates the resilience restoring force whereby the at least one needle 164 stops contacting the test contacts 2 and withdraws from the receiving recess 144 through the through-holes 1442, as shown in FIG. 7.

The fixing unit 20 is disposed on the test platform 12. After the external force F has been exerted upon the positioning module 14, the distance d between the positioning module 14 and the dial module 16 is fixed by the fixing unit 20 to thereby maintain the status quo of the at least one needle 164, that is, its insertion into the receiving recess 144 and its contact with the test contacts 2. To fix the distance d between the positioning module 14 and the dial module 16, the fixing unit 20 is snap-engaged with the positioning module 14. Conversely, once the fixing unit 20 is disengaged from the positioning module 14, the distance d between the positioning module 14 and the dial module 16 alters, and thus the at least one needle 164 is no longer in contact with the test contacts 2.

The clamping unit 22 is positioned proximate to the positioning module 14 for clamping the printed circuit board 4 in the receiving recess 144. The clamping unit 22 not only enables the printed circuit board 4 to be firmly received in the receiving recess 144 but also enhances the contact between the at least one needle 164 and the test contacts 2.

The accessing unit 24 is positioned beside the receiving recess 144 for allowing users to access the printed circuit board 4, such that users can take the printed circuit board 4 out of the receiving recess 144 or put the printed circuit board 4 in the receiving recess 144.

Accordingly, a printed circuit board testing device of the present invention can perform electrical tests on different types of printed circuit boards, and keep the shared test characteristics of the printed circuit boards by restricting replacement to a positioning module and a dial module.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A printed circuit board testing device for performing electrical tests on a printed circuit board having test contacts, the printed circuit board testing device comprising:
a test platform for carrying at least one electronic component, with a correlation between the at least one electronic component and the test contacts as far as the electrical tests are concerned;
a positioning module being mountable on and dismountable from the test platform and comprising a base formed thereon with a receiving recess having through-holes and receiving the printed circuit board, wherein the test contacts of the printed circuit board face the through-holes; and
a dial module comprising a bottom plate and a needle and selectively disposed between the test platform and the positioning module, wherein the needle is disposed on the bottom plate, corresponds in position to the through-holes, and is capable of penetrating the through-holes and inserting into the receiving recess to abut against the test contacts.

2. The printed circuit board testing device of claim 1, further comprising an elevating unit disposed between the test platform and the positioning module for altering a distance between the positioning module and the test platform.

3. The printed circuit board testing device of claim 2, wherein a decrease in the distance between the positioning module and the test platform causes the needle of the dial module to penetrate the through-holes and insert into the receiving recess to come into contact with the test contacts.

4. The printed circuit board testing device of claim 2, wherein an increase in the distance between the positioning module and the test platform causes the needle of the dial module to withdraw from the receiving recess through the through-holes and stop contacting the test contacts.

5. The printed circuit board testing device of claim 2, wherein the elevating unit is a spring.

6. The printed circuit board testing device of claim 2, further comprising a fixing unit disposed at the test platform for limiting the distance between the positioning module and the test platform.

7. The printed circuit board testing device of claim 1, further comprising a clamping unit positioned proximate to the receiving recess for clamping the printed circuit board in the receiving recess.

8. The printed circuit board testing device of claim 1, wherein the positioning module further comprises an accessing unit positioned beside the receiving recess for allowing the printed circuit board to be taken therefrom and put therein.
